(19) United States
(12) Patent Application Publication
(10) Pub. No.: US 2005/0009298 A1
(43) Pub. Date: Jan. 13, 2005

(54) Method for manufacturing semiconductor device

(76) Inventors: Shuichi Suzuki, Ichikawadaimon (JP); Hiroyuki Nagase, Ryuou (JP); Yasuharu Ichinose, Ryuou (JP); Teruhiro Mitsuyasu, Ryuou (JP)

Correspondence Address: MILES & STOCKBRIDGE PC, 1751 PINNACLE DRIVE, SUITE 500, MCLEAN, VA, 22102-3833, US

(21) Appl. No.: 10/485,734

(22) PCT Filed: Sep. 20, 2001
(86) PCT No.: PCT/JP01/08171

(51) Int. Cl. H01L 21/46; H01L 21/78; H01L 21/30; H01L 21/301; H01L 23/544

(52) U.S. Cl. 438/459; 257/797; 438/462; 438/464

(57) ABSTRACT

For marking a package efficiently at low cost, there is provided a dicing sheet 25 having transfer patterns 28A, 28B and an alignment mark 31 disposed at predetermined positions on a main surface of a base material 26, and an orientation flat 32 of a semiconductor wafer 1 and the alignment mark 31 are aligned with each other, then the main surface of the dicing sheet with the transfer patterns 28A, 28B and the alignment mark 31 disposed thereon and a back surface of the semiconductor wafer 1 are affixed to each other, and thereafter heat and pressure are applied to a back surface of the dicing sheet 25, thereby allowing the transfer patterns 28A and 28B to be transferred at a time to back surfaces of semiconductor chips from the dicing sheet 25.

### FIELD OF ART

The present invention relates to a semiconductor device manufacturing technique and more particularly to a technique which is effectively applicable to a method of marking a semiconductor device.

### BACKGROUND ART

On a surface of a semiconductor package (hereinafter referred to simply as “package”) there are marked a numeral or a symbol indicative of the package so that the product name, characteristics and lot number of the package can be recognized at a glance. Such a marking is applied in the following manner. Semiconductor chips are cut out from a semiconductor wafer, then are each packaged by resin sealing, and thereafter marking is applied thereto using a YAG (Yttrium Aluminum Garnet) laser for example. For example, in Japanese Published Unexamined Patent Application No. Hei 9(1997)-66519 there is disclosed a technique of bonding a marking tape having the aforesaid numeral or symbol to a package to effect marking.

The present inventors have been studying a method for carrying out a marking process efficiently. In the course of our study we found out that the following problems were involved in the above technique of packaging each semiconductor chip by resin sealing and thereafter marking the resulting package.

In the above technique, marking is performed for each individual package, so for increasing the number of packages to be produced it is required to increase the number of assembling lines and improve the marking speed for each package. However, increasing the number of assembling lines gives rise to the problem that the manufacturing cost rises although the number of packages produced increases. Likewise, increasing the marking speed for each package gives rise to the problem that it becomes difficult to effect marking in a simple manner.

It is an object of the present invention to provide a technique for applying marking efficiently to a package at low cost.

The above and other objects and novel features of the present invention will become apparent from the following description and the accompanying drawings.

### DISCLOSURE OF THE INVENTION

Typical modes of the present invention as disclosed herein will be outlined below.

The present invention comprises the steps of, prior to dividing a semiconductor wafer having a plurality of semiconductor chip-forming areas, thinning the semiconductor wafer by grinding a back surface of the wafer, and after grinding the back surface of the semiconductor wafer, forming an identification mark at a predetermined position on the back surface of each of the plural semiconductor chip-forming areas.

Further, the present invention comprises the steps of, prior to dividing a semiconductor wafer having a plurality of semiconductor chip-forming areas, forming a base film for bump electrodes on a main surface of the semiconductor wafer and thereafter patterning the base film, and after patterning the base film, forming an identification mark at a predetermined position on a back surface of each of the semiconductor chip-forming areas.

### BRIEF DESCRIPTION OF THE DRAWINGS

FIG. 1 is a manufacturing flow chart showing manufacturing steps in a semiconductor device manufacturing method according to a first embodiment of the present invention;

FIG. 2 is a manufacturing flow chart showing manufacturing steps which follow the manufacturing steps shown in FIG. 1;

FIG. 3 is a sectional view of a principal portion, showing the semiconductor device manufacturing method of the first embodiment;

FIG. 4 is a sectional view of a principal portion in a semiconductor device manufacturing step which follows FIG. 3;

FIG. 5 is a sectional view of a principal portion in a semiconductor device manufacturing step which follows FIG. 4;

FIG. 6 is a sectional view of a principal portion in a semiconductor device manufacturing step which follows FIG. 5;

FIG. 7 is a sectional view of a principal portion in a semiconductor device manufacturing step which follows FIG. 6;

FIG. 8 is a sectional view of a principal portion in a semiconductor device manufacturing step which follows FIG. 7;

FIG. 9 is a sectional view of a principal portion in a semiconductor device manufacturing step which follows FIG. 8;

FIG. 10 is a plan view of a dicing tape used in the semiconductor device manufacturing method of the first embodiment;

FIG. 11 is a sectional view of a principal portion of the dicing tape;

FIG. 12 is a perspective view of a principal portion, illustrating a transfer pattern forming step in the semiconductor device manufacturing method of the first embodiment;

FIG. 13 is a perspective view of a principal portion in the semiconductor device manufacturing method of the first embodiment;

FIG. 14 is a sectional view of a principal portion in a semiconductor device manufacturing step which follows FIG. 9;

FIG. 15 is a perspective view of a principal portion in a semiconductor device manufacturing step which follows FIG. 13;

FIG. 16 is a sectional view of a principal portion in a semiconductor device manufacturing step which follows FIG. 14;

FIG. 17 is a perspective view of a principal portion in a semiconductor device manufacturing step which follows FIG. 15;

FIG. 18 is a sectional view of a principal portion in a semiconductor device manufacturing step which follows FIG. 16;

FIG. 19 is a perspective view of a principal portion in a semiconductor device manufacturing step which follows FIG. 17;

FIG. 20 is a sectional view of a principal portion in a semiconductor device manufacturing step which follows FIG. 18;

FIG. 21 is a perspective view of a principal portion in a semiconductor device manufacturing step which follows FIG. 19;

FIG. 22 is a sectional view of a principal portion in a semiconductor device manufacturing step which follows FIG. 20;

FIG. 23 is a top view of the semiconductor device of the first embodiment;

FIG. 24 is a sectional view thereof;

FIG. 25 is a bottom view thereof;

FIG. 26 is a perspective view of a principal portion in the semiconductor device manufacturing method of the first embodiment;

FIG. 27 is a manufacturing flow chart showing a semiconductor device manufacturing method according to a second embodiment of the present invention;

FIG. 28 is a sectional view of a principal portion in the semiconductor device manufacturing method of the second embodiment;

FIG. 29 is a sectional view of a principal portion in a semiconductor device manufacturing step which follows FIG. 28;

FIG. 30 is a sectional view of a principal portion in a semiconductor device manufacturing step which follows FIG. 29;

FIG. 31 is a sectional view of a principal portion in a semiconductor device manufacturing step which follows FIG. 30;

FIG. 32 is a sectional view of a principal portion in a semiconductor device manufacturing step which follows FIG. 31;

FIG. 33 is a sectional view of a principal portion in a semiconductor device manufacturing step which follows FIG. 32;

FIG. 34 is a sectional view of a principal portion in a semiconductor device manufacturing step which follows FIG. 33;

FIG. 35 is a manufacturing flow chart showing a semiconductor device manufacturing method according to a third embodiment of the present invention;

FIG. 36 is a plan view showing the semiconductor device manufacturing method of the third embodiment;

FIG. 37 is a sectional view of a principal portion, showing a semiconductor device manufacturing step in the third embodiment;

FIG. 38 is a sectional view of a principal portion in a semiconductor device manufacturing step which follows FIG. 37;

FIG. 39 is a sectional view of a principal portion in a semiconductor device manufacturing step which follows FIG. 38;

FIG. 40 is a manufacturing flow chart showing a semiconductor device manufacturing method according to a fourth embodiment of the present invention;

FIG. 41 is a plan view of a marking sheet used in the semiconductor device manufacturing method of the fourth embodiment;

FIG. 42 is a sectional view of a principal portion, showing a semiconductor device manufacturing step in the fourth embodiment;

FIG. 43 is a sectional view of a principal portion in a semiconductor device manufacturing step which follows FIG. 42;

FIG. 44 is a sectional view of a principal portion in a semiconductor device manufacturing step which follows FIG. 33;

FIG. 45 is a manufacturing flow chart showing a semiconductor device manufacturing method according to a fifth embodiment of the present invention;

FIG. 46 is a sectional view of a principal portion, showing a semiconductor device manufacturing step in the fifth embodiment;

FIG. 47 is a sectional view of a principal portion in a semiconductor device manufacturing step which follows FIG. 46;

FIG. 48 is a sectional view of a principal portion in a semiconductor device manufacturing step which follows FIG. 47;

FIG. 49 is a sectional view of a principal portion in a semiconductor device manufacturing step which follows FIG. 48;

FIG. 50 is a manufacturing flow chart showing a semiconductor device manufacturing method according to a sixth embodiment of the present invention;

FIG. 51 is a sectional view of a principal portion, showing a semiconductor device manufacturing step in the sixth embodiment;

FIG. 52 is a plan view of a principal portion, showing a semiconductor device manufacturing step in the sixth embodiment;

FIG. 53 is a sectional view of a principal portion in a semiconductor device manufacturing step which follows FIG. 51;

FIG. 54 is a sectional view of a principal portion in a semiconductor device manufacturing step which follows FIG. 53; and

FIG. 55 is a sectional view of a principal portion in a semiconductor device manufacturing step which follows FIG. 54.

### BEST MODE FOR CARRYING OUT THE INVENTION

Embodiments of the present invention will be described in detail hereinunder with reference to the accompanying drawings. In all of the drawings for illustrating the embodiments, components having the same functions are identified by the same reference numerals, and repeated explanations thereof will be omitted.

### FIRST EMBODIMENT

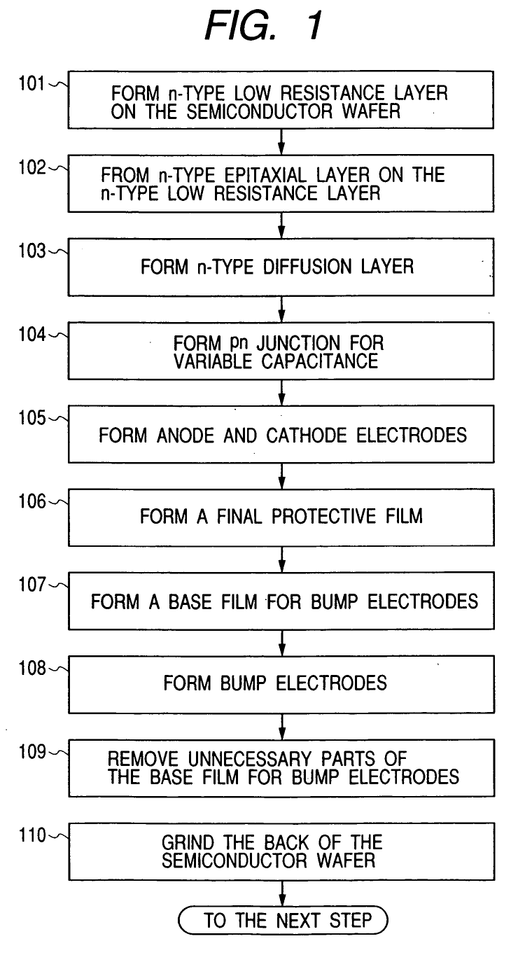

A semiconductor device according to this first embodiment is, for example, a CSP (Chip Size Package) type variable capacitance diode. A method for manufacturing the semiconductor device according to this first embodiment will be described below with reference to FIGS. 1 to 25.

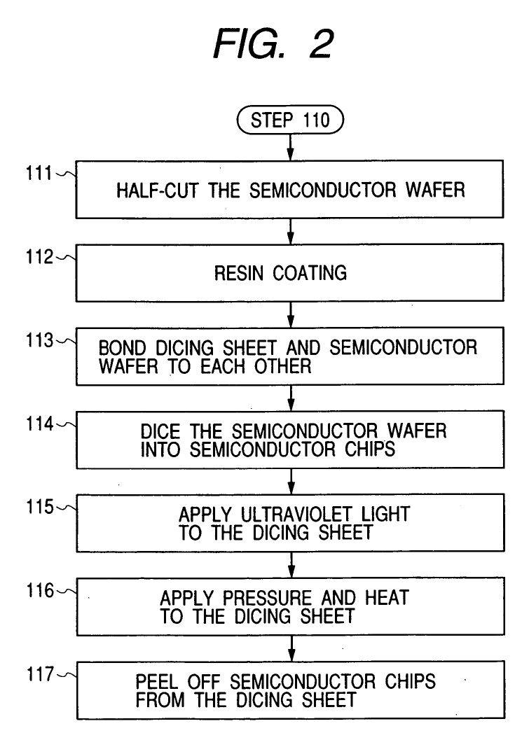

FIGS. 1 and 2 are manufacturing flow charts showing an outline of manufacturing steps for the package of the first embodiment, which steps are steps 101 to 117.

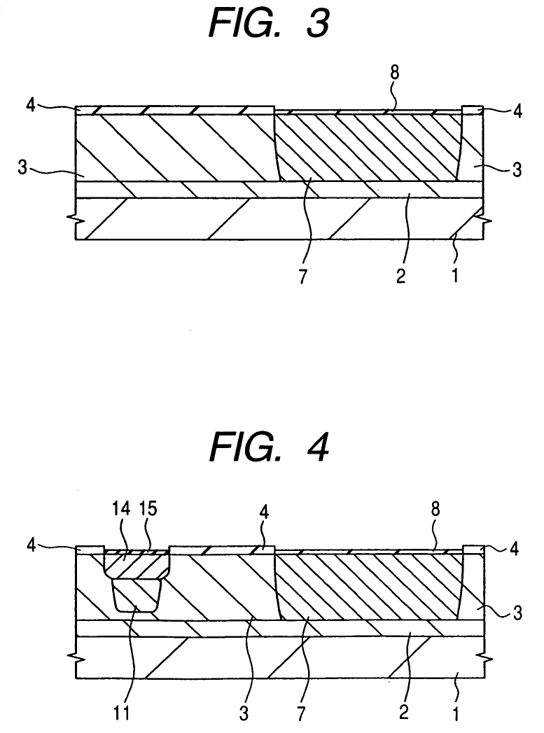

First, as shown in FIG. 3, there is provided a semiconductor wafer 1 of a single crystal silicon having p-type conductivity and a resistivity of about 10 Ωcm. For example, As (arsenic) ions are introduced into the semiconductor wafer 1. Subsequently, the As ions are diffused by applying heat to the semiconductor wafer 1 to form an n-type low resistance layer 2 (step 101). Then, an n⁻-type epitaxial layer 3 is formed on the n-type low resistance layer 2 in accordance with a vapor phase growth method (step 102).

Next, silicon oxide film 4 is formed on a surface of the n⁻-type epitaxial layer 3 in accordance with a thermal oxidation method. Subsequently, photoresist film (not shown) is formed on the silicon oxide film 4 and thereafter, with the photoresist film as a mask, the silicon oxide film 4 is etched to form an aperture in the silicon oxide film 4. Thereafter, with the photoresist film as a mask, for example P (phosphorus) ions are introduced through the aperture into the n⁻-type epitaxial layer 3. Subsequently, heat is applied to the semiconductor wafer 1 to diffuse the P ions, thereby forming an n⁺-type diffusion layer 7 (step 103). Next, silicon oxide film 8 is formed on a surface of the n⁺-type diffusion layer 7 in accordance with a thermal oxidation method.

Then, the photoresist film which has been used for forming the n⁺-type diffusion layer 7 is removed, thereafter, as shown in FIG. 4, photoresist film (not shown) is newly formed on the semiconductor wafer 1, and with the photoresist film as a mask, the silicon oxide film 4 is etched to form an aperture in the silicon oxide film 4. Next, with that photoresist film as a mask, for example P ions are introduced through the aperture into the n⁻-type epitaxial layer 3. Subsequently, the semiconductor wafer 1 is heat-treated, allowing the P ions to diffuse, thereby forming an n⁺-type semiconductor layer 11.

Then, the photoresist film which has been used for forming the n⁺-type semiconductor layer 11 is removed and thereafter photoresist film (not shown) is newly formed on the semiconductor wafer 1, then with the photoresist film as a mask, the silicon oxide film 4 is etched to form an aperture in the silicon oxide film 4. Subsequently, with the photoresist film as a mask, for example B (boron) ions are introduced through the aperture into the n⁻-type epitaxial layer 3. Next, the semiconductor wafer 1 is heat-treated, allowing the B ions to diffuse, thereby forming a p⁺-type diffusion layer 14. By the steps so far described it is possible to form a pn junction which comprises the p⁺-type diffusion layer 4, n⁺-type semiconductor layer 11, n⁻-type epitaxial layer 3, n-type low resistance layer 2, and n⁺-type diffusion layer 7, (step 104). Thereafter, silicon oxide film 15 is formed on a surface of the p⁺-type diffusion layer 14 by a thermal oxidation method.

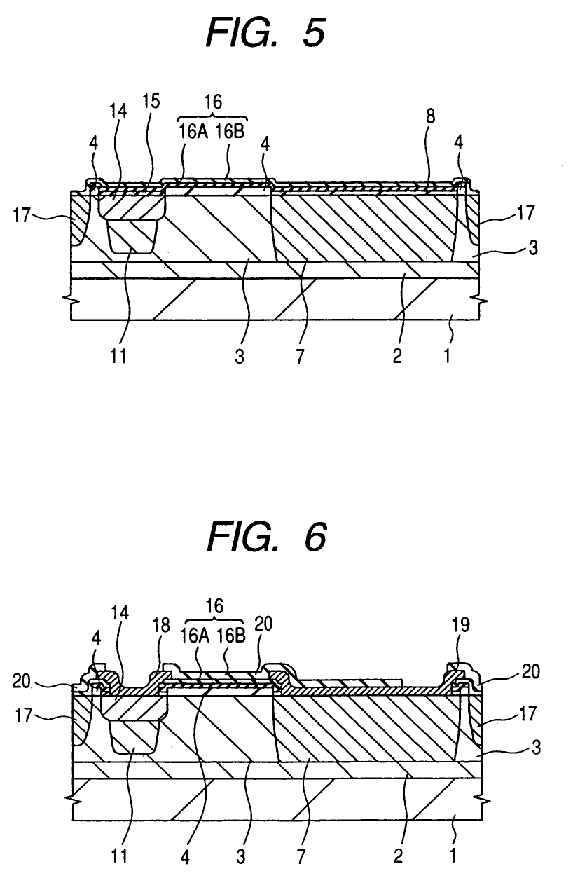

Next, the photoresist film which has been used for forming the p⁺-diffusion layer 14 is removed, and thereafter, as shown in FIG. 5, silicon oxide film 16A is formed on the semiconductor wafer 1 by a thermal oxidation method. Subsequently, with photoresist film (not shown) as a mask, the silicon oxide film 16A is etched to form an aperture in the same film. Then, with that photoresist film as a mask, for example P ions are introduced through the aperture into the n⁻-type epitaxial layer 3 to form a channel stopper layer 17.

Then, the photoresist film which has been used for forming the channel stopper layer 17 is removed, thereafter, PSG (Phospho Silicate Glass) film 16B is deposited to form an intermediate protective film 16 which comprises the silicon oxide film 16A and the PSG film 16B.

Next, as shown in FIG. 6, with photomask (not shown) as a mask, the intermediate protective film 16 and the silicon oxide films 8, 15 are etched to form an aperture which reaches the p⁺-type diffusion layer 14 and an aperture which reaches an n⁺-type diffusion layer 7. Subsequently, the photoresist film is removed and thereafter a metal film such as Al (aluminum) alloy or W (tungsten) film is deposited. Thereafter, the metal film is patterned by etching to form an anode electrode 18 connected electrically to the p⁺-type diffusion layer 14 and a cathode electrode 19 connected electrically to the n⁺-type diffusion layer 7 (step 105).

Then, silicon nitride film is deposited on the semiconductor wafer 1 by a CVD method for example. Subsequently, with photoresist film as a mask, the silicon nitride film is etched to form a final protective film 20 (step 106).

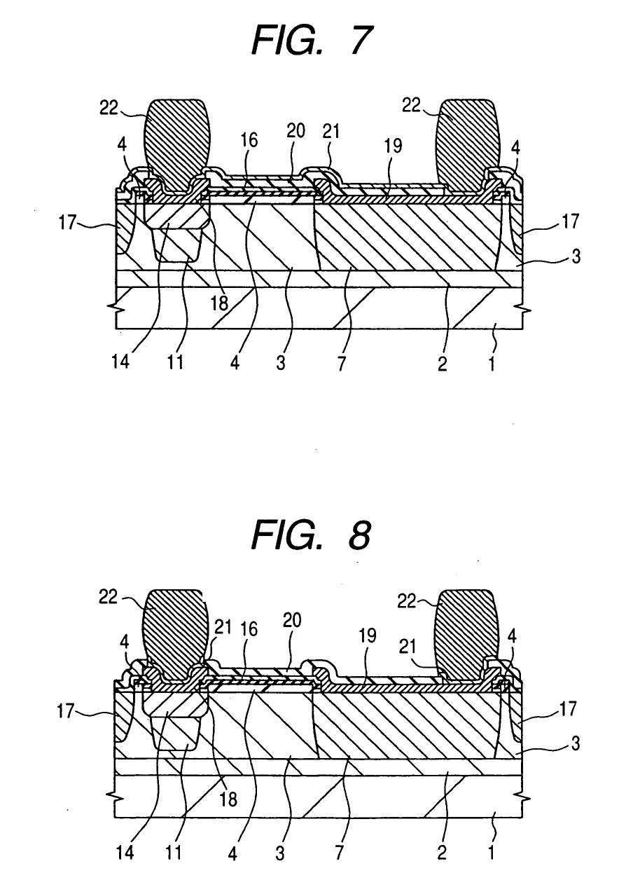

Next, as shown in FIG. 7, Ti (titanium) film and Ni (nickel) film are vapor-deposited successively from below onto the semiconductor wafer 1 to form a base film (base electrode) 21 for bump electrodes (step 107). At this time, Pd (palladium) film may be vapor-deposited instead of Ni film.

Then, photoresist film (not shown) is applied onto the base film 21 for bump electrodes and apertures are formed selectively in the photoresist film by a photolithography technique to form bump electrode-forming areas. Thereafter, bump electrodes 22 are formed in the bump electrode-forming areas (step 108). The material of the bump electrodes 22 may be selected to match the material of the electrode formed at the position where the variable capacitance diode in the first embodiment is mounted. For example, when the electrode located at that mounting position is formed of Au (gold), Cu (copper) film is deposited by plating in the areas where bump electrodes are to be formed and then Au film is deposited by plating on the surface of the Cu film, whereby bump electrodes 22 can be formed. Ni (nickel) film may be deposited by plating instead of the Cu film. When the electrode in the above mounting position is formed using solder, the bump electrodes 22 may be formed using solder.

Next, as shown in FIG. 8, the photoresist film which has been used for forming the bump electrodes 22 is removed and thereafter, by wet etching using, for example, a potassium hydroxide solution or an ammonium iodide solution, the base film 21 for bump electrodes is removed while allowing the base film 21 which underlies the bump electrodes 22 to remain unremoved (step 109). In this way the base film 21 for bump electrodes is patterned.

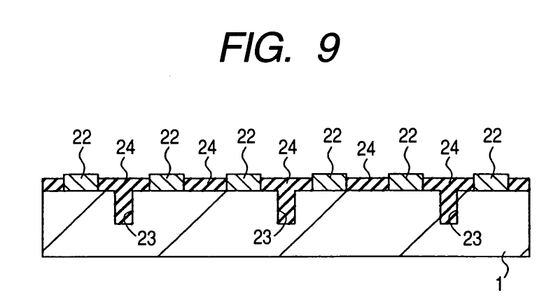

Then, a back surface of the semiconductor wafer 1 is subjected to grinding to thin the wafer (step 110). Subsequently, in a chip-forming surface (main surface) of the semiconductor wafer 1, as shown in FIG. 9, grooves 23 are formed by a half-cut method in dividing areas which divide the semiconductor wafer into individual chip-forming areas (step 111). For example, the depth of each groove 23 is about half of the thickness of the semiconductor wafer 1. It is assumed that the semiconductor wafer 1 is partitioned to tens of thousands of semiconductor chip-forming areas by the above dividing areas. Then, for example, resin 24 is applied to the chip-forming surface of the semiconductor wafer including the interiors of the grooves 23 to effect sealing (step 112). As a result, even after division of the semiconductor wafer 1 into individual chips by the dividing areas, the resin 24 present within the grooves 23 covers side faces of semiconductor chips, whereby it is possible to strengthen the force of bonding between the resin 24 and the semiconductor chips. Consequently, it is possible to prevent the resin 24 and the semiconductor chips from peeling off each other and hence possible to improve the moistureproof reliability and light shielding property of the semiconductor chips.

FIG. 9 is illustrated so that the sections of plural semiconductor chip-forming areas can be seen. This is for making the package manufacturing process of this first embodiment easier to see.

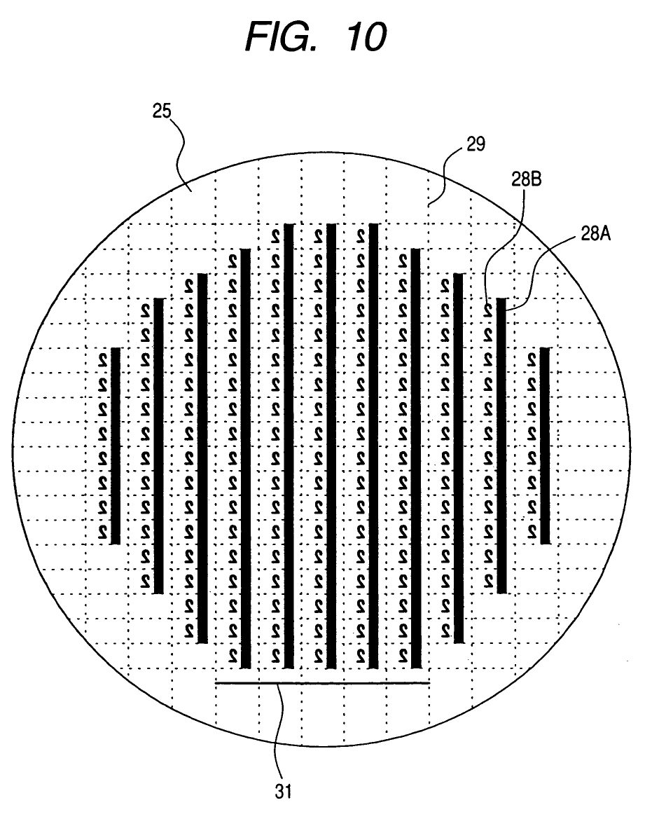

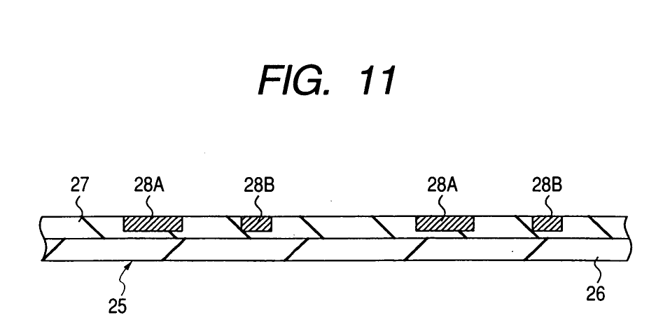

Next, such a dicing sheet 25 as shown in FIGS. 10 and 11 is provided the dicing sheet 25 is fabricated by applying an ultraviolet-curing type adhesive 27 onto a base material 26 of, for example, polyethylene, polyvinyl, or polyolefin and printing transfer patterns (materials) 28A and 28B of In (indium) for example onto the adhesive 27. A main surface (first surface) of the dicing sheet 25 with the adhesive 27 and transfer patterns 28A, 28B thus disposed thereon is partitioned by dicing lines 29 to match the profile of each semiconductor chip, and the transfer patterns 28A and 28B are disposed at predetermined positions in each of the thus-partitioned areas. In the drawings, the transfer patterns 28A are disposed band-like at predetermined positions in each of the partitioned areas, but they may be dots or arrows, not bands. As noted above, the semiconductor wafer 1 is partitioned into tens of thousands of semiconductor chip-forming areas and the main surface of the dicing sheet 25 is also partitioned accordingly. But in FIG. 10 the number of areas partitioned by the dicing lines 29 is reduced in order to make such areas easier to see.

The transfer patterns 28A and 28B are disposed in an inverted state on the base material 26, and by transferring them onto the back surfaces of semiconductor chips in a later step it is possible to make them respectively into polar identification marks and product identification marks. Further, In is superior in light reflectance, so by forming those polar identification marks and product identification marks by In it is possible to improve their visibility. For example, as shown in FIG. 12, such transfer patterns 28A and 28B can be formed by disposing a metallic plate 30 of, for example, Fe (iron)-Ni (nickel) onto the base material 26 with the adhesive 27 applied thereto and then vapor-depositing In into a groove 30A and an apertures 30B formed in the metallic plate 30. Although the metallic plate 30 is used in this first embodiment, it may be substituted, for example, by a heat-resisting film of PET (Polyethylene Terephthalate). In FIG. 12 there is shown only one area partitioned to match the profile of each semiconductor chip.

On the adhesive 27 is formed an alignment mark (second mark) 31 (see FIG. 10) for alignment at the time of bonding the semiconductor wafer 1 and the dicing sheet 25. For example, the alignment mark 31 is disposed correspondingly to an orientation flat position of the semiconductor wafer 1. By bonding the semiconductor wafer 1 and the dicing sheet 25 with each other in an aligned state of both the orientation flat position and the position of the alignment mark 31 it is possible to ensure a high alignment accuracy at the time of disposing the transfer patterns 28A and 28B on the back surface of each semiconductor chip. For example, the alignment mark 31 may be formed by a method wherein, in the above step of forming the transfer patterns 28A and 28B, an aperture corresponding to the alignment mark 31 is formed in the metallic plate 30 and then In is vapor-deposited through the aperture thus formed as is the case with transfer patterns 28A and 28.

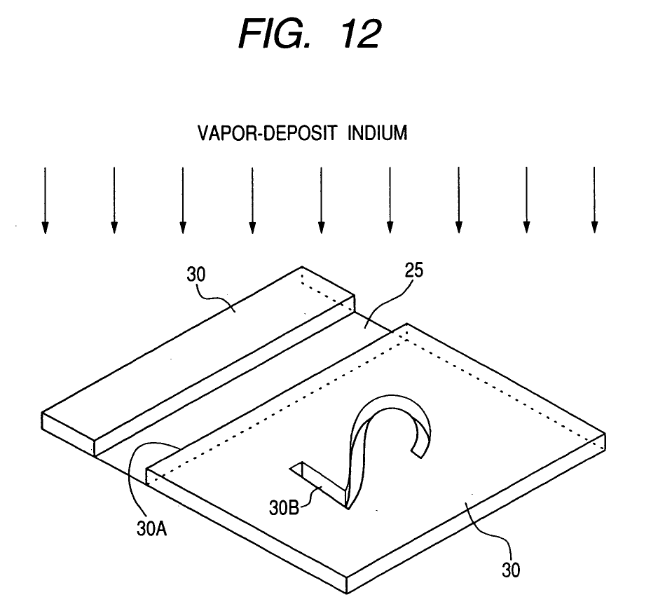

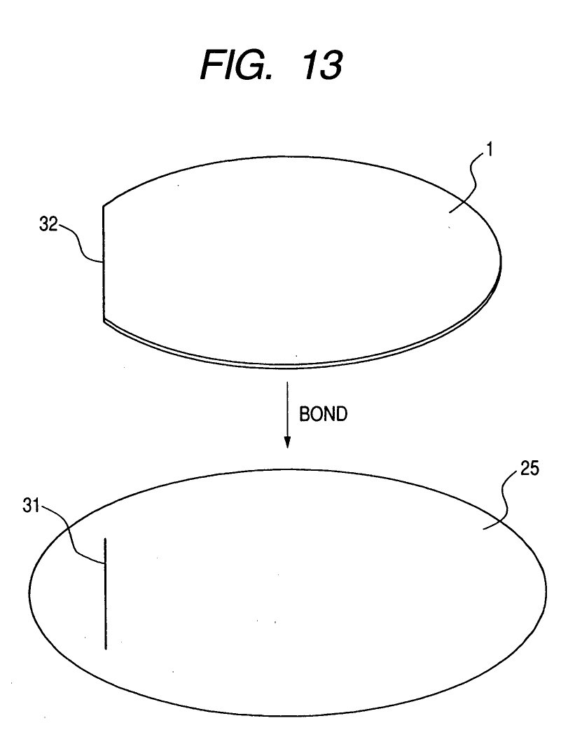

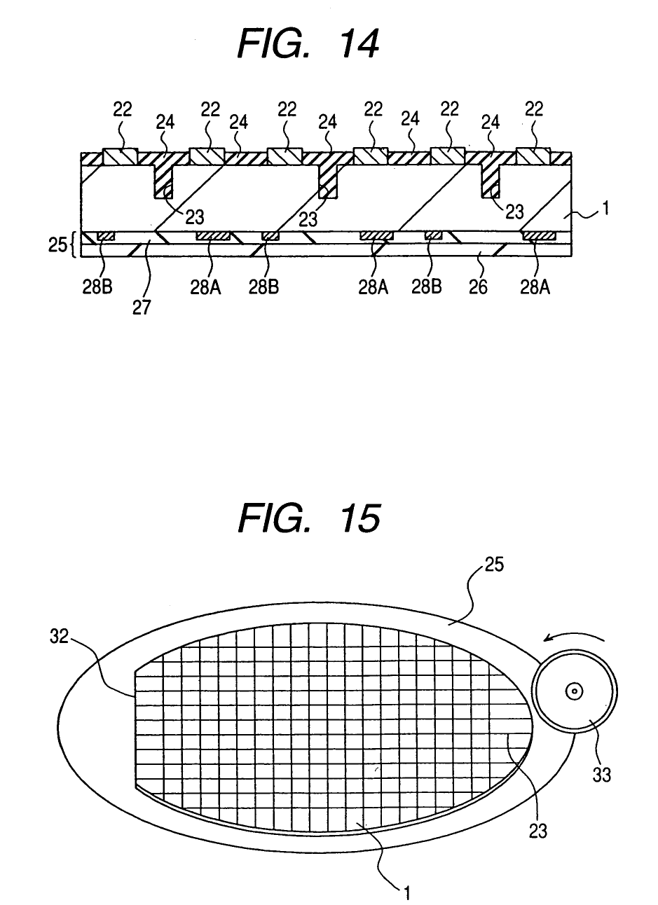

Next, as shown in FIGS. 13 and 14, an orientation flat (first mark) 32 of the semiconductor wafer 1 and the alignment mark 31 are aligned with each other and the back surface of the semiconductor wafer 1 and the main surface (the surface on which the transfer patterns 28A and 28B are formed) of the dicing sheet 25 are affixed to each other (step 113).

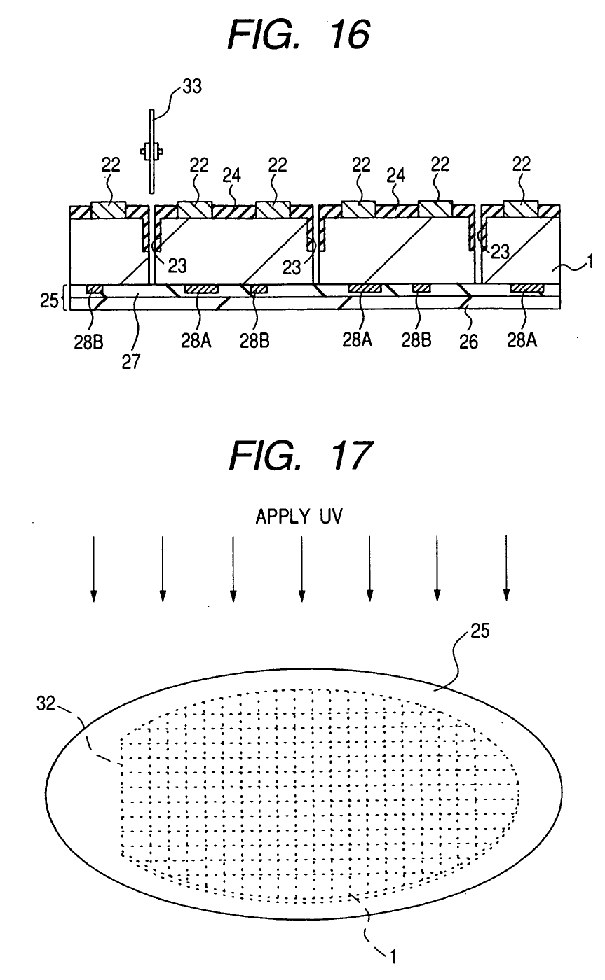

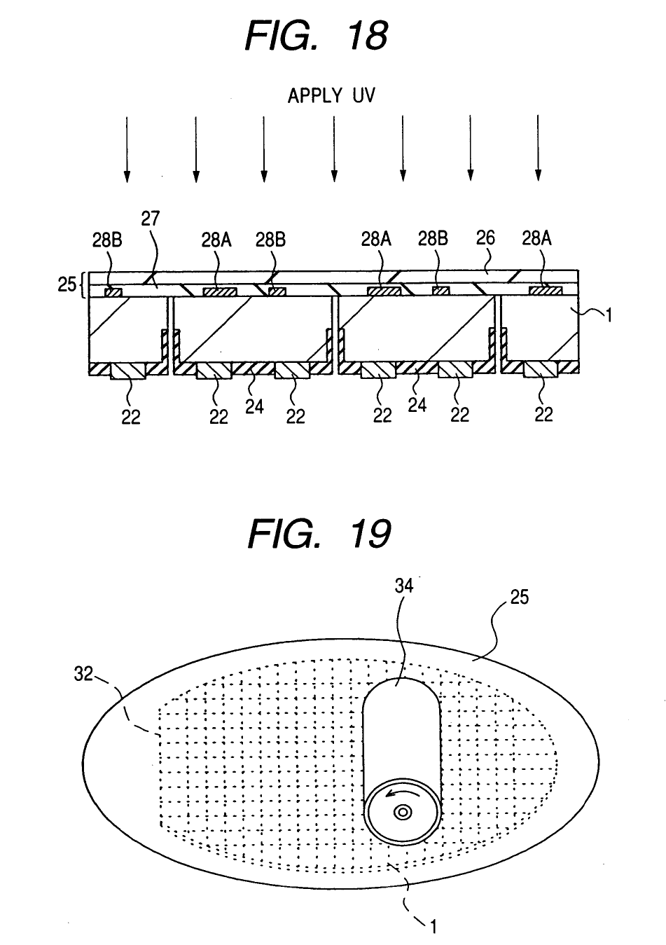

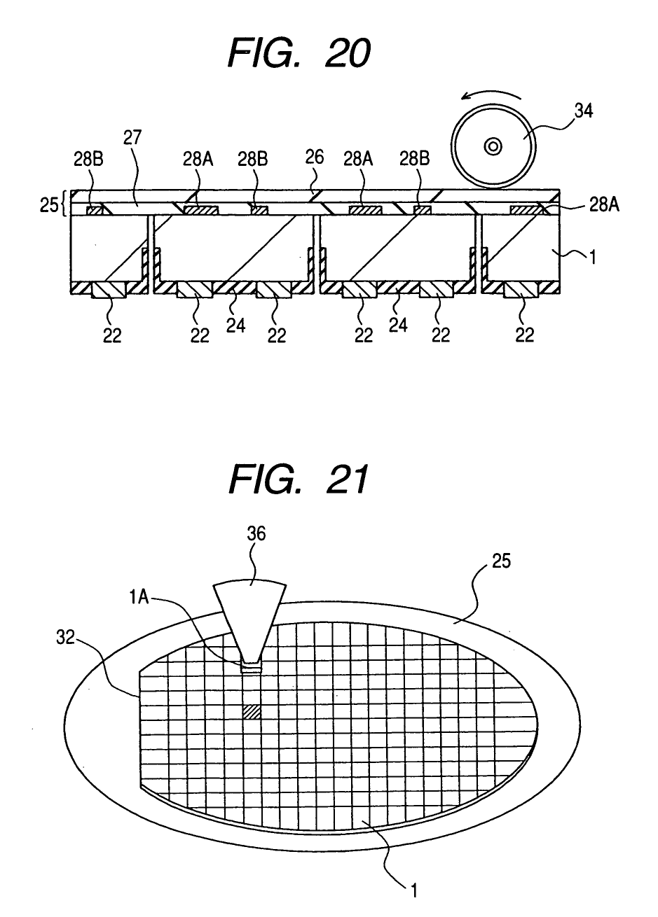

Then, as shown in FIGS. 15 and 16, the semiconductor wafer 1 is diced along the grooves 23 with use of a dicing blade 33 for example to divide the wafer into individual semiconductor chips (step 114). Subsequently, as shown in FIGS. 17 and 18, the adhesive 27 is cured by applying ultraviolet light to the back surface of the dicing sheet 25 step 115). Thereafter, as shown in FIGS. 19 and 20, pressure is applied to the back surface of the dicing sheet 25 with use of a roller 34 for example and then the dicing sheet is heat-treated at a temperature of about 160° C. or higher to eutecticize the transfer patterns 28A, 28B with silicon of the semiconductor wafer 1, whereby the transfer patterns 28A and 28B can be transferred at a time from the dicing sheet 25 to the back surface of each semiconductor chip and thus it is possible to effect marking (step 116). Prior to such a pressure and heat applying step, the semiconductor wafer 1 has been divided into individual semiconductor chips in step 114 (see FIGS. 15 and 16) and therefore can be prevented from being cracked in other areas than the dividing areas (grooves 23) by the application of pressure and heat in step 116.

It is preferable that the above marking step be carried out after the step 109 of removing unnecessary parts of the base film 21 for bump electrodes. When the marking step 116 precedes the unnecessary parts removing step 109, the transfer patterns 28A and 28B which have been transferred to the back surface of the semiconductor chip are also removed by wet etching at the time of removing unnecessary parts of the base film 21 for bump electrodes. In this first embodiment the occurrence of such an inconvenience can be prevented by carrying out the marking step 116 after the unnecessary parts removing step 109.

It is preferable that the marking step 116 be carried out after the step 110 of grinding the back surface of the semiconductor wafer 1. That is, if unnecessary thin film is formed on the back surface of the semiconductor wafer 1 and if marking is performed in this state, there sometimes occurs a case where the transfer patterns 28A and 28B are difficult to be transferred to the back surface of each semiconductor chip. Therefore, as in this first embodiment, by performing the marking step 116 after the wafer back grinding step 110, it is possible to remove the thin film and hence it is possible to prevent the occurrence of such an inconvenience as the transfer patterns 28A and 28B are difficult to be transferred to the back surface of each semiconductor chip.

In this first embodiment, as described above, it is possible to effect marking at a time for the back surfaces of tens of thousands of semiconductor chips produced from the semiconductor wafer 1. Thus, the marking efficiency can be greatly improved in comparison with the case where individual semiconductor chips are subjected one by one to marking. In this way the number of packages manufactured can be increased without increasing the package assembling lines in this first embodiment. Besides, it is possible to suppress a rise of the package manufacturing cost because it is not necessary to increase the package assembling lines. That is, according to this first embodiment, the number of packages manufactured can be increased while suppressing a rise of the package manufacturing cost.

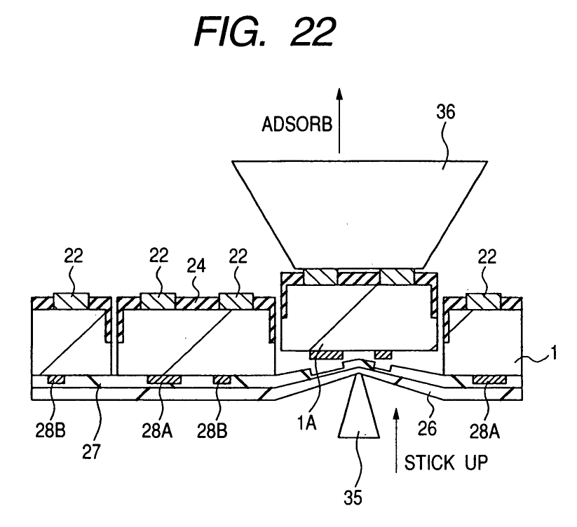

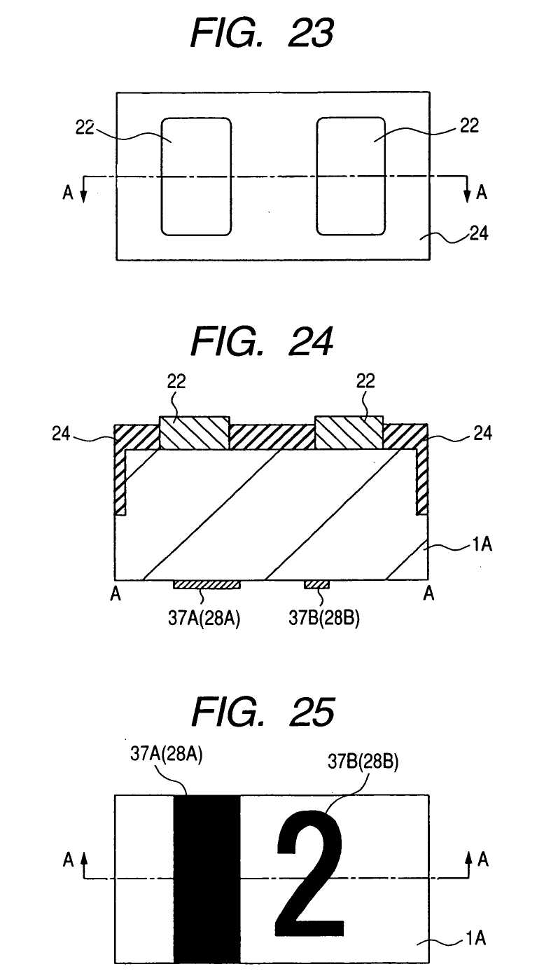

Next, as shown in FIGS. 21 and 22, the dicing sheet 25 which underlies a semiconductor chip 1A is stuck up by a stick-up pin 35 and in this state the semiconductor chip 1A is adsorbed by a vacuum chuck collet 36 to peel off the semiconductor chip from the dicing sheet 25 (step 117). In this way it is possible to fabricate such a package of this first embodiment as shown in FIGS. 23 to 25, which are a top view, a sectional view, and a bottom view, respectively, of the package. In FIG. 24, the illustration of an interior device construction is omitted. The transfer patterns 28A and 28B which have been transferred to the back surface of the semiconductor chip 1A can be formed as polar identification mark 37A and product identification mark (identification mark) 37B, respectively, (see FIG. 25). For example, on the back surface of the semiconductor chip 1A, the polar identification mark 37A is formed on the cathode 19 (see FIG. 6) side of the variable capacitance diode in this first embodiment. According to this first embodiment, the polar identification mark 37A and the product identification mark 37B are formed by transferring In which has been patterned on the dicing sheet 25 onto the back surface of the semiconductor chip 1A, whereby, in comparison with the case where the polar identification mark 37A and the product identification mark 37B are formed by a laser, their profiles can be made clearer and therefore it is possible to improve their detection ability and accuracy.

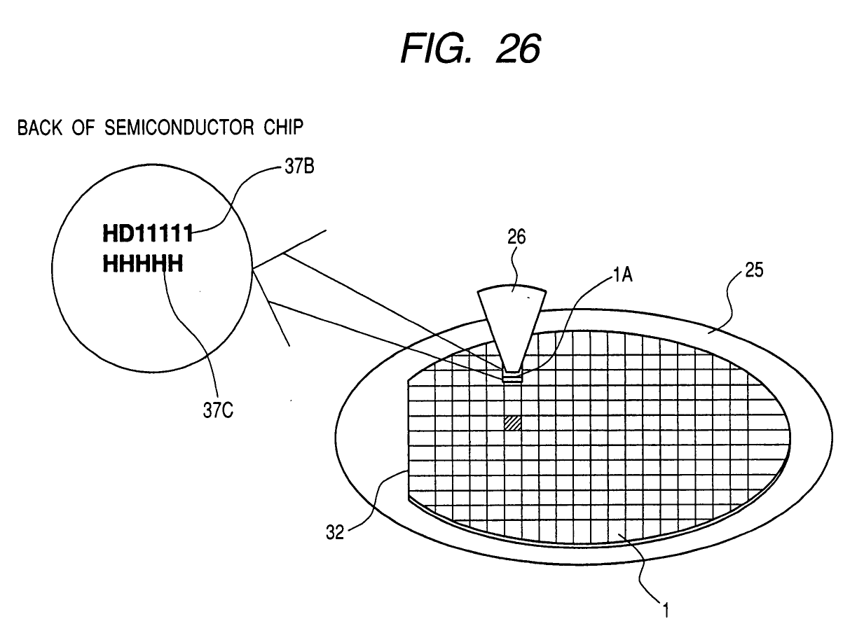

Although in the first embodiment described above the present invention was applied mainly to the package of a variable capacitance diode as a background application field of the invention by the inventors, no limitation is made thereto, but the invention is also applicable for example to a multi-pin type package having such a logic circuit as a microprocessor. In such a multi-pin type package it is not necessary to form the polar identification mark 37A (see FIG. 25) on the back surface of a semiconductor chip, but instead there may be formed such a manufacturer identification mark 37C as shown in FIG. 26. The manufacturer identification mark 37C can also be formed through the same step as the step of forming the polar identification mark 37A and the product identification mark 37B (see FIG. 25).

Thus, according to the first embodiment it is possible to obtain the following effects.

(1) Since marking can be applied at a time to the back surfaces of plural semiconductor chips which are produced from a semiconductor wafer, the marking efficiency can be greatly improved in comparison with the case where individual semiconductor chips are subjected one by one to marking.

(2) Since it is possible to increase the number of manufactured packages without increasing the number of package assembling lines, it is possible to suppress a rise of the package manufacturing cost.

### SECOND EMBODIMENT

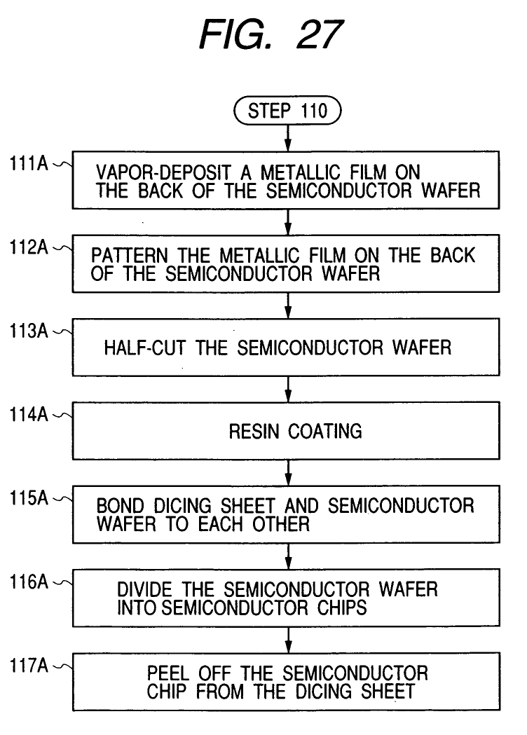

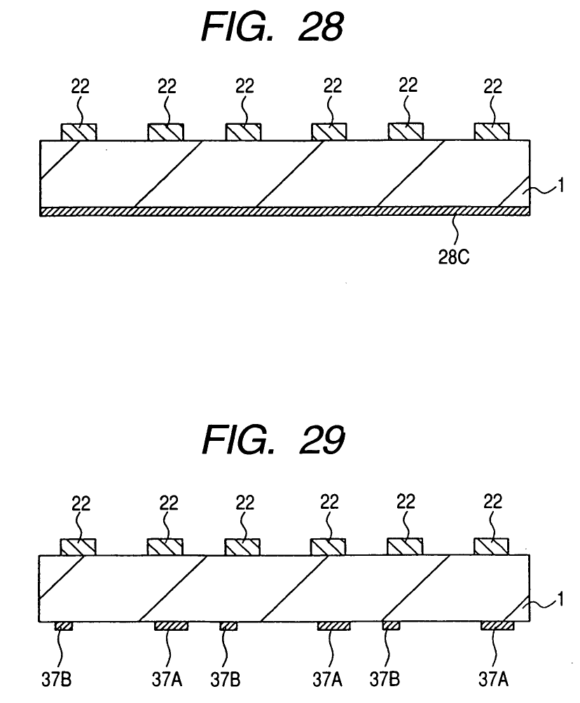

A semiconductor device manufacturing method according to this second embodiment is a modification of the semiconductor device manufacturing method of the previous first embodiment. The method of this second embodiment will be described below with reference to FIGS. 27 to 34.

FIG. 27 is a manufacturing flow chart showing an outline of a part of a package manufacturing process according to this second embodiment, in which steps 111A to 117A are package manufacturing steps included in the process.

The steps 101 to 110 (see FIG. 1) described above in connection with FIGS. 3 to 8 in the previous first embodiment also apply to the semiconductor manufacturing method of this second embodiment. Thereafter, as shown in FIG. 29, a metallic film (first thin film) 28C of for example In or Al is vapor-deposited to the back surface of the semiconductor wafer 1 (step 111A). Then, using as mask a photoresist film (not shown) which has been subjected to patterning by a photolithography technique, the metallic film 28C is dry-etched to form the polar identification mark 37A and the product identification mark 37B both described in the first embodiment (step 112A). At this time, on the back surface of the semiconductor wafer 1, the polar identification mark 37A and the product identification mark 37B can be disposed at predetermined positions within each semiconductor chip-forming area.

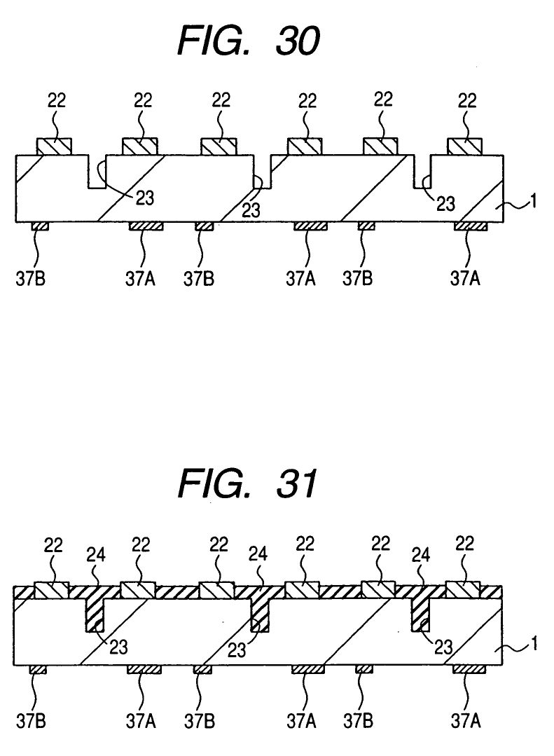

Subsequently, as shown in FIG. 30, on the chip-forming surface (main surface) of the semiconductor wafer 1, grooves 23 are formed in dividing areas which divide the semiconductor wafer 1 into individual semiconductor chip-forming areas (step 113). For example, the depth of each groove 23 is set to about half of the thickness of the semiconductor wafer 1.

Next, as shown in FIG. 31, for example resin 24 is applied onto the chip-forming surface of the semiconductor wafer 1, including the interiors of the grooves 23, to effect resin sealing (step 114A). As a result, even after dividing the semiconductor wafer 1 in the dividing areas into individual semiconductor chips, the resin 24 present within the grooves 23 covers the side faces of the semiconductor chips, so that it is possible to enhance the bonding force between the resin 24 and the semiconductor chips. Consequently, the resin 24 and the semiconductor chips can be prevented from peeling off each other and hence it is possible to improve the moistureproof reliability and light shielding property of the semiconductor chips.

In the photography step for forming the polar identification mark 37A and the product identification mark 37B and during conveyance of the semiconductor wafer 1, a mechanical load is imposed on the semiconductor wafer 1. Conversely to the process of this second embodiment, if the grooves 23 are formed before formation of the polar identification mark 37A and the product identification mark 37B, there occurs an inconvenience such that the semiconductor wafer 1 is apt to be cracked in the vicinity of the grooves 23 at the time of forming both marks 37A and 37B. In this second embodiment, for preventing the occurrence of such an inconvenience, the formation of the grooves 23 and the resin sealing with the resin 24 are carried out after both marks 37A and 37B have been formed on the back surface of the semiconductor wafer 1.

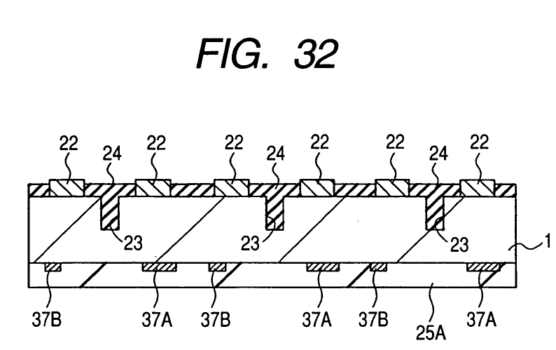

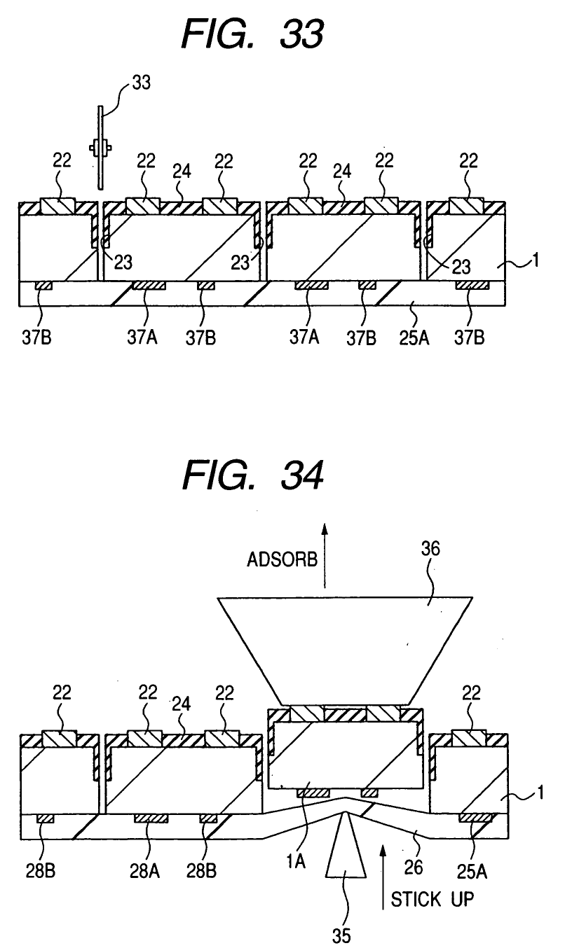

Then, as shown in FIGS. 32, the back surface of the semiconductor wafer 1 is bonded to a dicing sheet 25A which is formed of, for example, polyethylene, polyvinyl, or polyolefin, (step 115A). Subsequently, as shown in FIG. 33, the semiconductor wafer 1 is diced along the grooves 23 with use of a dicing blade 33 for example and is thereby divided into individual chips (step 116A). Thereafter, as shown in FIG. 34, the dicing sheet 25A which underlies the semiconductor chip 1A is stuck up with a stick-up pin 35 and in this state a semiconductor chip 1A is adsorbed by means of a vacuum chuck collet 36 and is thereby peeled off from the dicing sheet 25A (step 117A). In this way it is possible to fabricate the package of this second embodiment.

Also in this second embodiment constructed as above it is possible to obtain the same effects as in the previous first embodiment.

### THIRD EMBODIMENT

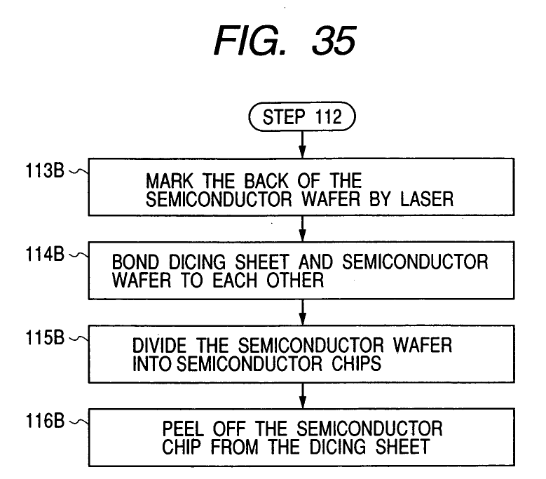

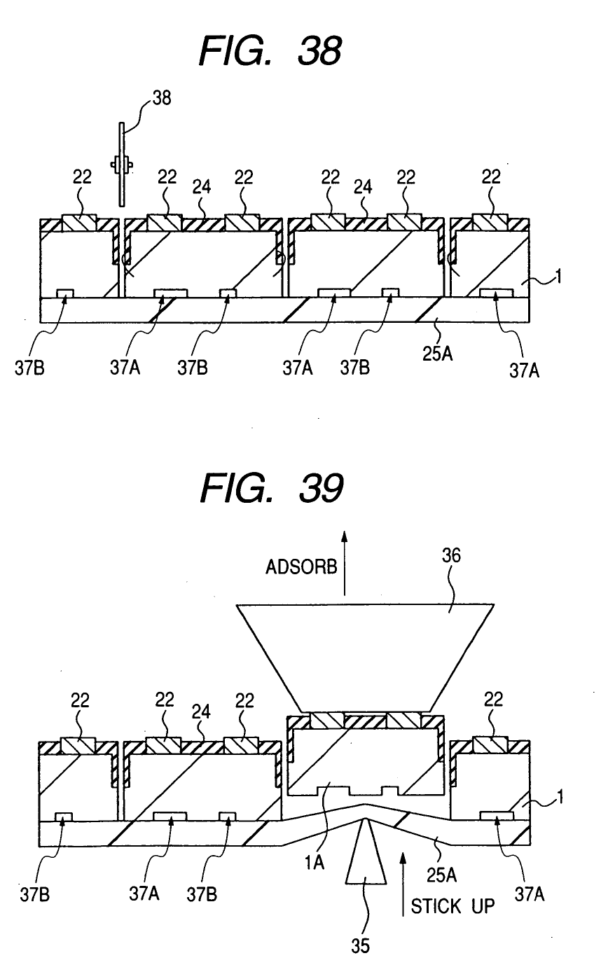

A semiconductor device manufacturing method according to this third embodiment is a modification of the semiconductor device manufacturing methods described in the previous first and second embodiments. The semiconductor device manufacturing method of this third embodiment will be described below with reference to FIGS. 35 to 39.

FIG. 35 is a manufacturing flow chart showing an outline of a part of a package manufacturing process according to this third embodiment, in which steps 113B to 116B are package manufacturing steps included in the process.

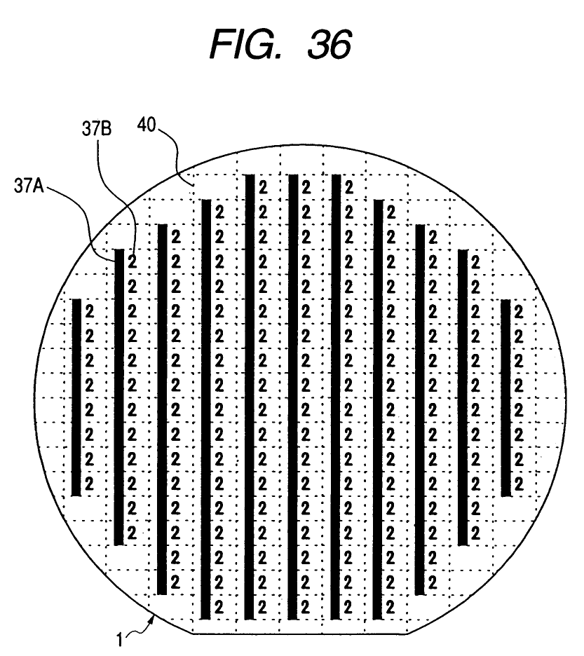

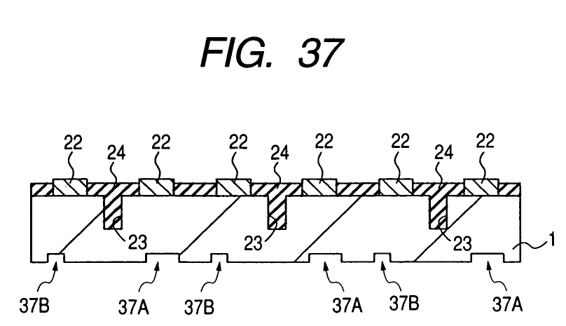

The steps 101 to 112 (see FIG. 1) described above in connection with FIGS. 3 to 9 in the first embodiment also apply to the semiconductor device manufacturing method of this third embodiment. Thereafter, as shown in FIG. 36 which illustrates the back surface of the semiconductor wafer 1 and FIG. 37 which is a sectional view showing a principal portion of the semiconductor wafer 1, the back surface of the semiconductor wafer 1 is melted by radiating thereto a laser beam using, for example, He (helium) or Ne (neon) to form solar identification marks 37A and product identification marks 37B (step 113B). At this time, there may be adopted, for example, a method wherein both marks 37A and 37B are formed by scanning the back surface of the semiconductor wafer 1 directly with a laser beam or a method wherein both plural marks 37A and 37B are formed at a time by radiating a laser beam through a mask. According to these methods, on the back surface of the semiconductor wafer 1, each polar identification mark 37A and product identification mark 37B can be disposed at predetermined positions within each of semiconductor chip-forming areas which are defined by dividing areas 40.

The step of forming the polar identification marks 37A and product identification marks 37B with use a laser beam as in this third embodiment may be carried out before the step 108 (see FIG. 1) of forming bump electrodes 22 (see FIG. 7) described in the first embodiment. This is for the following reason. In this third embodiment, unlike the first and second embodiments, the polar identification marks 37A and the product identification marks 37B are formed not by a metallic film but by melting the back surface of the semiconductor wafer 1, so that in the step 109 (see FIG. 1) of removing unnecessary parts of the base film 21 for bump electrodes it is possible to prevent removal of both marks 37A and 37B.

Next, as shown in 38, the back surface of the semiconductor wafer 1 is bonded to a dicing sheet 25A which is formed of, for example, polyethylene, polyvinyl, or polyolefin, (step 114B). Subsequently, using a dicing blade 33 for example, the semiconductor wafer 1 is diced along grooves 23 and is thereby divided into individual semiconductor chips (step 115B). Then, as shown in FIG. 39, the dicing sheet 25A which underlies a semiconductor chip 1A is stuck up with a stick-up pin 35 and in this state the semiconductor chip 1A is adsorbed by means a vacuum chuck collet 36 and is thereby peeled off from the dicing sheet 25A (step 116B). In this way it is possible to fabricate the package of this third embodiment.

Also in this third embodiment it is possible to obtain the same effects as in the first and second embodiments.

### FOURTH EMBODIMENT

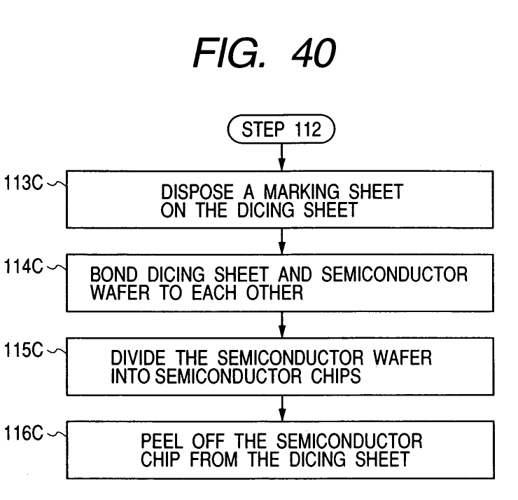

A semiconductor device manufacturing method according to this fourth embodiment is a modification of the semiconductor device manufacturing method of the previous first to third embodiments. The semiconductor device manufacturing method of this fourth embodiment will be described below with reference to FIGS. 40 to 44.

FIG. 40 is a manufacturing flow chart showing an outline of a part of a package manufacturing process according to this fourth embodiment, in which steps 113C to 116C are manufacturing steps included in the process.

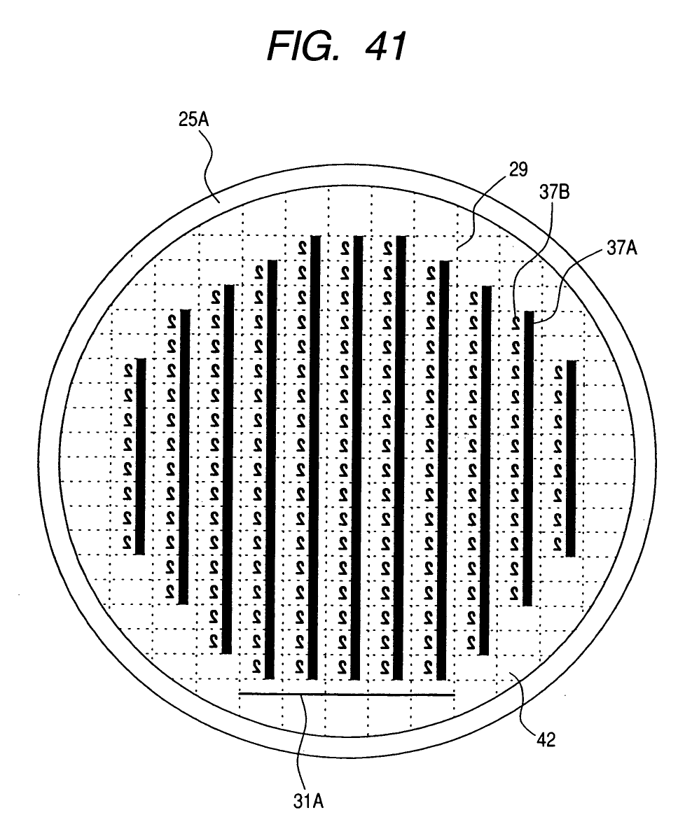

The steps 101 to 112 (see FIG. 1) described above in connection with FIGS. 3 to 9 in the first embodiment also apply to the semiconductor device manufacturing method of this fourth embodiment. Thereafter, as shown in FIG. 41, a marking sheet (first sheet) 42 with polar identification marks 37A and product identification marks 37B printed thereon is disposed on a main surface of a dicing sheet 25A (step 113C). The marking sheet 42 is partitioned by dicing lines 29 to match the profile of each semiconductor chip, and the polar identification marks 37A and the product identification marks 37B are each disposed at predetermined positions in each of the partitioned areas. Both marks 37A and 37B are disposed in an inverted state on the dicing sheet 25A and can be restored from the inverted state by affixing the marking sheet 42 to the back surface of the semiconductor chips.

On the marking sheet 42 is formed an alignment mark 31 for aligning the marking sheet 42 with the semiconductor wafer 1 at the time of affixing the former to the latter. For example, the alignment mark 31 is disposed correspondingly to an orientation flat position of the semiconductor wafer 1. That is, by bonding the marking sheet 42 to the back surface of the semiconductor wafer 1 while aligning the orientation flat and the aligning mark 31 with each other, it is possible to ensure a high alignment accuracy at the time of disposing the polar identification marks 37A and the product identification marks 37B on the backs of the semiconductor chips.

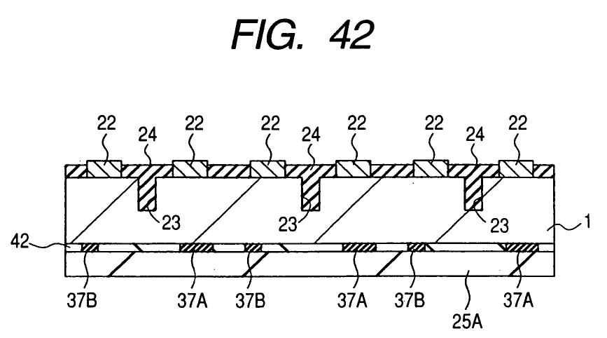

Next, as shown in FIG. 42, the orientation flat of the semiconductor wafer 1 and the alignment mark 31 are aligned with each other and the back surface of the semiconductor wafer 1 and a main surface of the dicing sheet 25A are affixed together, thereby affixing the marking sheet 42 to the back surface of the semiconductor wafer 1 (step 114C). At this time, the bonding force between the semiconductor wafer 1 and the marking sheet 2 stronger than the bonding force between the dicing sheet 25A and the marking sheet 42.

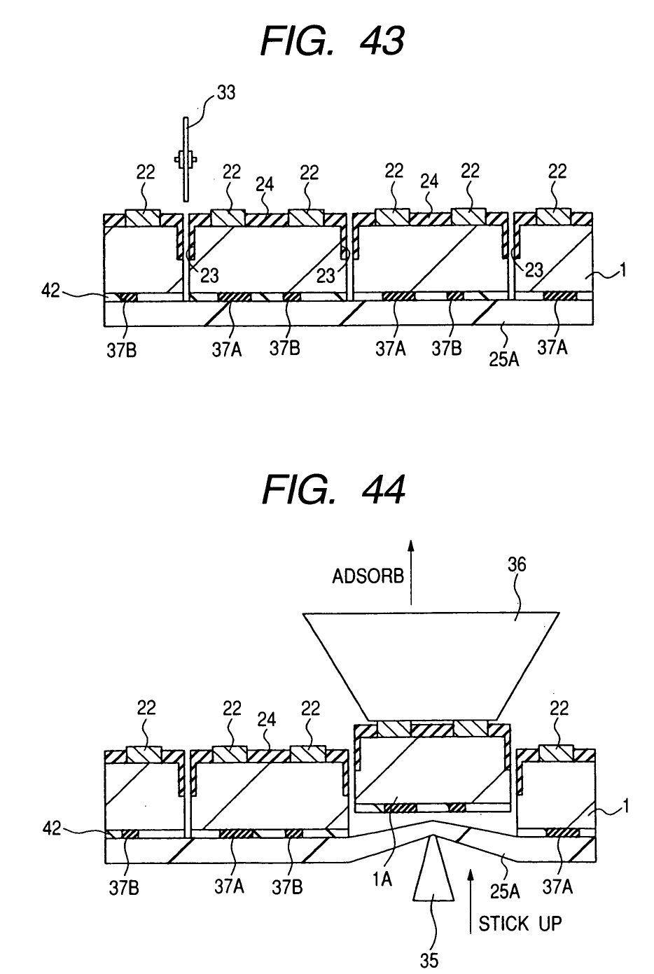

Subsequently, as shown in FIG. 43, using a dicing blade 33 for example, the semiconductor wafer 1 and the marking sheet 42 are diced along grooves 23 to divide the semiconductor wafer into individual semiconductor chips (step 115C). Next, as shown in FIG. 44, the dicing sheet 25A which underlies a semiconductor chip 1A is stuck up with a stick-up pin 35 and in this state the semiconductor chip 1A is adsorbed by means of a vacuum chuck collet 36 and is thereby peeled off from the dicing sheet 25A to afford the semiconductor device of this fourth embodiment (step 116C). At this time, the semiconductor chip 1A can be peeled off from the dicing sheet 25A in the affixed state of the marking sheet 42 to the back surface of the semiconductor chip 1A because the marking sheet has been divided in the same shape as the profile of the semiconductor chip 1A in the dicing step for the semiconductor wafer 1.

In this fourth embodiment it is possible suppress cracking of the semiconductor chips and damage to the semiconductor elements in the semiconductor chips because the dicing sheet pressurizing and heating step 116 (see FIGS. 2, 19 and 20) shown in the first embodiment is not used in this fourth embodiment. Also in this fourth embodiment it is possible to obtain the same effects as in the first and second embodiments.

### FIFTH EMBODIMENT

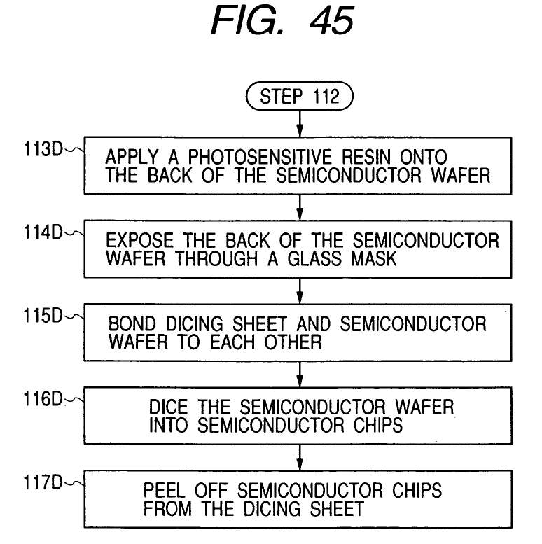

A semiconductor device manufacturing method according to this fifth embodiment is a modification of the semiconductor device manufacturing methods described in the previous first to fourth embodiments. The semiconductor device manufacturing method of this fifth embodiment will be described below with reference to FIGS. 45 to 49.

FIG. 45 is a manufacturing flow chart showing an outline of a part of a package manufacturing process according to this fifth embodiment, in which steps 113D to 117D describes respective manufacturing steps.

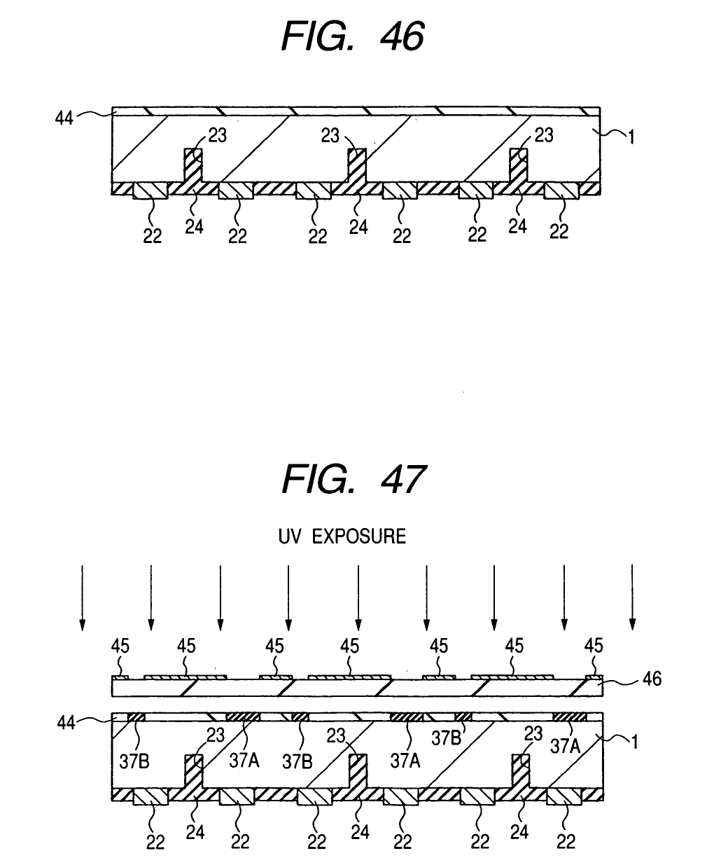

The steps 101 to 112 (see FIG. 1) described above in connection with FIGS. 3 to 9 in the first embodiment also apply to the semiconductor device manufacturing method of this fifth embodiment. Thereafter, as shown in FIG. 46, a photosensitive resin film (second thin film) 44 is applied to the back surface of the semiconductor wafer 1 (step 113D).

Subsequently, as shown in FIG. 47, the resin film 44 is exposed to ultraviolet light for example, using as mask a glass plate 46 with light shielding patterns 45 of Cr (chromium) formed on a surface thereof, (step 114D). In this case, the light shielding patterns 45 have been subjected to patterning beforehand in conformity with the profiles of polar identification marks and product identification marks which are formed on the backs of the semiconductor chips. In this exposure step, therefore, on the back surface of the semiconductor wafer 1, the resin film 44 senses light at predetermined positions in each semiconductor chip-forming area, causing a change of contrast, so that it is possible to form polar identification marks 37A and product identification marks 37B.

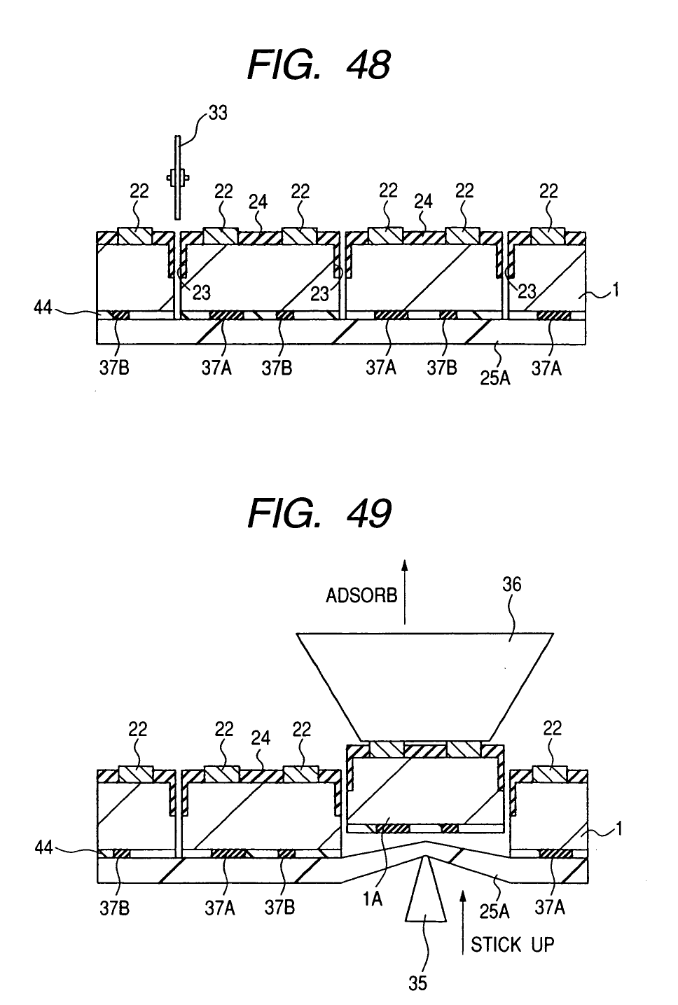

Then, as shown in FIG. 48, using a dicing blade 33 for example, the semiconductor wafer 1 and the resin film 44 are diced along grooves 23 to divide the semiconductor wafer 1 into individual semiconductor chips (step 116D). Thereafter, as shown in FIG. 49, a dicing sheet 25A which underlies a semiconductor chip 1A is stuck up with a stick-up pin 35 and in this state the semiconductor chip 1A is adsorbed by means of a vacuum chuck collet 36 and is thereby peeled off from the dicing sheet 25A to fabricate the semiconductor device of this fifth embodiment (step 117D).

According to this fifth embodiment, both polar identification marks 37A and product identification marks 37B can be transferred all together to a plurality of semiconductor chip-forming areas, so that it is possible to shorten the transfer step. Further, also in this fifth embodiment it is possible to obtain the same effects as in the first embodiment.

### SIXTH EMBODIMENT

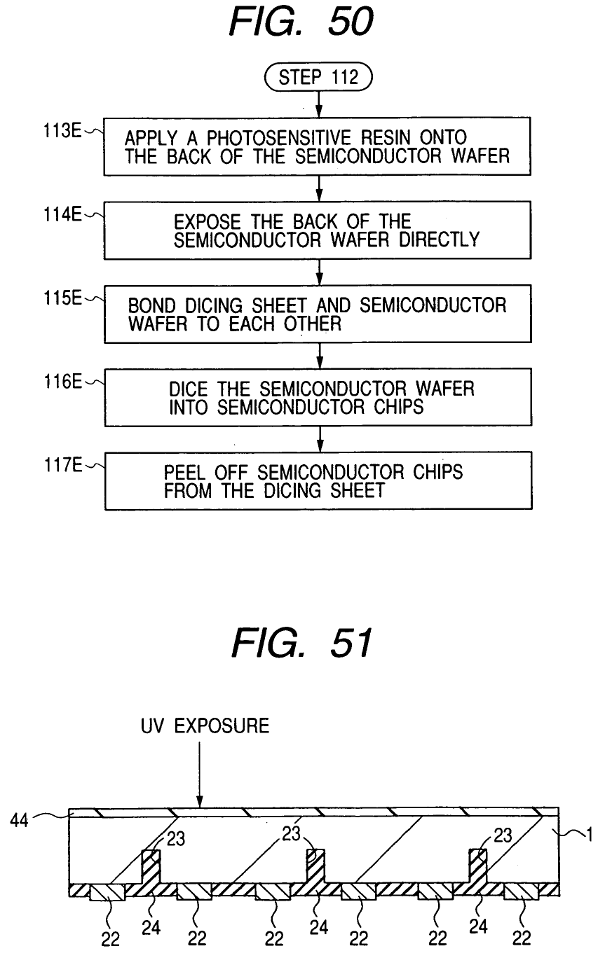

A semiconductor device manufacturing method according to this sixth embodiment is a modification of the semiconductor device manufacturing method described in the fifth embodiment. The semiconductor device manufacturing method of this sixth embodiment will be described below with reference to FIGS. 50 and 51.

FIG. 50 is a manufacturing flow chart showing an outline of a part of a package manufacturing process according to this sixth embodiment, in which steps 113E to 117E are manufacturing steps included in the process.

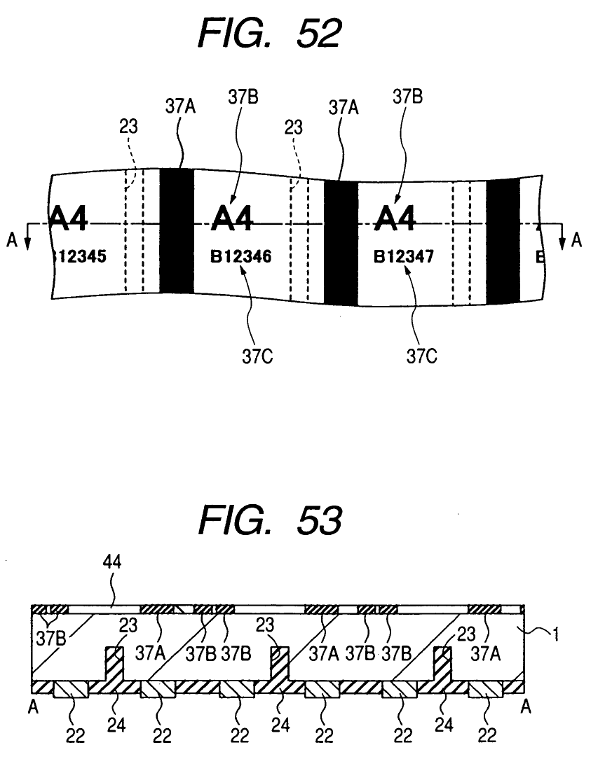

The steps 101 to 112 (see FIG. 1) described above in connection with FIGS. 3 to 9 in the first embodiment also apply to the semiconductor device manufacturing method of this sixth embodiment. Thereafter, as shown in FIG. 51, a photosensitive resin film 44 is applied to the back surface of the semiconductor wafer 1 (step 113E). Subsequently, ultraviolet light having a radiation spot of a reduced diameter is applied to and scans the resin film 44 directly without using any mask, allowing the resin film 44 to sense the light, whereby such polar identification marks 37A, product identification marks 37B and chip ID (Identification Number) marks 37C as shown in FIGS. 52 and 53 are described. By so doing, a different number or symbol can be affixed as a chip ID mark 37C to each semiconductor chip and therefore it becomes possible to give a production lot number as a chip ID mark 37C for each semiconductor chip production lot.

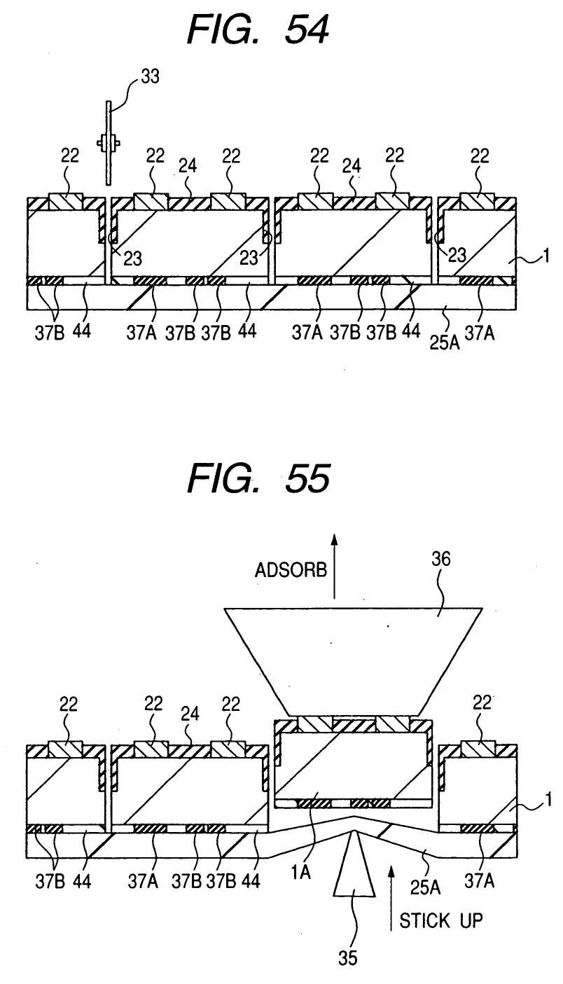

Subsequently, as shown in FIG. 54, using a dicing blade 33 for example, the semiconductor wafer 1 and the resin film 44 are diced along grooves 23 to divide the semiconductor wafer into individual semiconductor chips (step 116E). Then, as shown in FIG. 55, a dicing sheet 25A which underlies a semiconductor chip 1A is stuck up with a stick-up pin 35 and in this state the semiconductor chip 1A is adsorbed by means of a vacuum chuck collet 36 and is thereby peeled off from the dicing sheet 25A to fabricate the semiconductor device of this sixth embodiment (step 117E).

Also in this sixth embodiment it is possible to obtain the same effects as in the first and second embodiment.

Although the present invention has been described above concretely on the basis of embodiments thereof, it goes without saying that the present invention is not limited to the above embodiments, but that various changes may be made within the scope not departing from the gist of the invention.

For example, although in the first embodiment the polar identification marks and the product identification marks are formed using In, there may be used Al which is superior in visibility. In this case, the temperature of the heat treatment for eutecticizing silicon of the semiconductor wafer with Al is set to about 400° C. or higher.

Industrial Applicability

As set forth above, the present invention is particularly effective in its application to semiconductor devices to be mounted on mobile communication devices, including portable telephone, as well as memory cards and IC cards.

1-53. (cancelled)

54. A method for manufacturing a semiconductor device, comprising the steps of:
(a) providing a semiconductor wafer having a plurality of semiconductor chip-forming areas;
(b) grinding a back surface of the semiconductor wafer to thin the semiconductor wafer;
(c) providing a base material having a transfer material over a first surface thereof, the transfer material being patterned in a predetermined shape, disposed correspondingly to predetermined positions in the plural semiconductor chip-forming areas;
(d) after the step (b), affixing the back surface of the semiconductor wafer and the first surface of the base material to each other;
(e) transferring the transfer material from the first surface of the base material to the back surface of the semiconductor wafer to form identification marks of the transfer material respectively at the predetermined positions in the plural semiconductor chip-forming areas; and
(e) cutting the semiconductor wafer to divide the wafer into a plurality of semiconductor chips.

55. The method of claim 54, wherein the identification marks each represent selected one or more of polarity, as well as product name, ID and manufacturer's name of the associated one of the semiconductor chips.

56. A method for manufacturing a semiconductor device, comprising the steps of:
(a) providing a semiconductor wafer having a plurality of semiconductor chip-forming areas;
(b) forming a plurality of bump electrodes at predetermined positions over a main surface of the semiconductor wafer;
(c) grinding a back surface of the semiconductor wafer to thin the wafer;
(d) after the step (b) and (c), forming a first thin film including indium or aluminum as a main component over the back surface of the semiconductor wafer; and
(e) patterning the first thin film in a predetermined shape to form identification marks respectively at predetermined positions in the plural semiconductor chip-forming areas over the back surface of the semiconductor wafer; and
(f) cutting the semiconductor wafer to divide the wafer into a plurality of semiconductor chips.

57. A method for manufacturing a semiconductor device, comprising the steps of:
(a) providing a semiconductor wafer having a plurality of semiconductor chip-forming areas;
(b) forming a plurality of bump electrodes at predetermined positions over a main surface of the semiconductor wafer;
(c) grinding a back surface of the semiconductor wafer to thin the wafer;
(d) providing a first sheet having printed thereover identification marks corresponding respectively to predetermined positions in the plural semiconductor chip-forming areas;
(e) after the step (b) and (c), affixing the first sheet to the back surface of the semiconductor wafer to dispose the identification marks respectively at the predetermined positions in the plural semiconductor chip-forming areas; and
(f) cutting the semiconductor wafer to divide the wafer into a plurality of semiconductor chips.

58. A method for manufacturing a semiconductor device, comprising the steps of:
(a) providing a semiconductor wafer having a plurality of semiconductor chip-forming areas;
(b) forming a base film for bump electrodes over a main surface of the semiconductor wafer and thereafter patterning the base film;
(c) providing a base material having a transfer material over a first surface thereof, the transfer material being patterned in a predetermined shape, disposed correspondingly to predetermined positions in the plural semiconductor chip-forming areas;
(d) after the step (b), affixing a back surface of the semiconductor wafer and the first surface of the base material to each other;
(e) transferring the transfer material from the first surface of the base material to the back surface of the semiconductor wafer to form identification marks respectively at the predetermined positions in the plural semiconductor chip-forming areas; and
(f) cutting the semiconductor wafer to divide the wafer into a plurality of semiconductor chips.

59. The method of claim 58, wherein the identification marks each represent selected one or more of polarity, as well as product name, ID and manufacturer's name of the associated one of the semiconductor chips.

60. A method for manufacturing a semiconductor device, comprising the steps of:
(a) providing a semiconductor wafer having a plurality of semiconductor chip-forming areas;
(b) forming a base film for bump electrodes over a main surface of the semiconductor wafer and thereafter patterning the base film;
(c) after the step (b), forming a first thin film over the back surface of the semiconductor wafer, the first thin film including indium or aluminum as a main component;
(d) patterning the first thin film in a predetermined shape to form identification marks respectively at predetermined positions in the plural semiconductor chip-forming areas over the back surface of the semiconductor wafer; and
(e) cutting the semiconductor wafer to divide the wafer into a plurality of semiconductor chips,
wherein the step (b) comprises the steps of:
(b1) forming a plurality of bump electrodes at predetermined positions over the base film; and
(b2) allowing a portion of the base film which underlies the plural bump electrodes to remain, and removing the other portion of the base film.

61. A method for manufacturing a semiconductor device, comprising the steps of:
(a) providing a semiconductor wafer having a plurality of semiconductor chip-forming areas;
(b) forming a base film for bump electrodes over a main surface of the semiconductor chip and thereafter patterning the base film;
(c) providing a first sheet having printed thereover identification marks corresponding respectively to predetermined positions in the plural semiconductor chip-forming areas;
(d) affixing the first sheet to the back surface of the semiconductor wafer to dispose the identification marks respectively at the predetermined positions in the plural semiconductor chip-forming areas; and
(e) cutting the semiconductor wafer to divide the wafer into a plurality of chips,
wherein the step (b) comprises the steps of:
(b1) forming a plurality of bump electrodes at predetermined positions over the base film; and
(b2) allowing a portion of the base film which underlies the plural bump electrodes to remain, and removing the other portion of the base film.

62. A method for manufacturing a semiconductor device, comprising the steps of:
(a) providing a semiconductor wafer having a plurality of semiconductor chip-forming areas partitioned by dividing areas;
(b) forming a base film for bump electrodes over a main surface of the semiconductor wafer and thereafter patterning the base film;
(c) after the step (b), forming an insulating film for sealing over the semiconductor wafer;
(d) after the step (c), forming identification marks respectively at predetermined positions in the plural semiconductor chip-forming areas over a back surface of the semiconductor wafer; and
(e) cutting the semiconductor wafer and the insulating film for sealing along the dividing areas to divide the semiconductor wafer into a plurality of semiconductor chips.

63. The method according to claim 62, wherein the step (c) comprises the steps of:
(c1) forming grooves in the dividing areas over the main surface of the semiconductor wafer; and
(c2) forming an insulating film for sealing over the main surface of the semiconductor chip to fill up the grooves.

64. The method according to claim 62, wherein the identification marks each represent selected one or more of polarity, as well as product name, ID and manufacturer's name of the associated one of the semiconductor chips.
